(19) United States
(12) Patent Application Publication
(10) Pub. No.: US 2008/0116983 A1
(43) Pub. Date: May 22, 2008

(54) PLL LOCK DETECTION CIRCUIT AND SEMICONDUCTOR DEVICE

(75) Inventors: Norihide Kinugasa, Kyoto (JP); Sachi Ota, Osaka (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/943,227

(22) Filed: Nov. 20, 2007

(30) Foreign Application Priority Data
Nov. 21, 2006 (JP) 2006-314246

(51) Int. Cl. H03L 7/06

(52) U.S. Cl. 331/25; 327/156

(57) ABSTRACT

A PLL lock detection circuit produces a high precision PLL lock detection signal and enables eliminating a smoothing circuit. The PLL lock detection circuit reliably detects if the PLL circuit is locked reliably and without error by simultaneously evaluating both locked and unlocked states. A continuity detection unit detects if a PLL locked state continues for H consecutive periods, and another continuity detection unit detects if a PLL unlocked state continues for H consecutive periods. The continuity detection units simultaneously output the PLL locked/unlocked states, and an R-S latch holds the detection result.

### BACKGROUND OF THE INVENTION

1. Field of Invention

The present invention relates to technology for detecting the phase state of a PLL circuit, and relates more particularly to a PLL lock detection circuit and semiconductor device.

2. Description of Related Art

In a video display system according to the related art that has a VCO (voltage-controlled oscillator) synchronized to the horizontal sync signal (or composite sync signal) of the video signal, the PLL lock detection circuit requires a smoothing circuit unit 700 as shown in FIG. 7. One drawback to this arrangement is that integrating the PLL lock detection circuit requires external pins and externally connected components (a smoothing capacitance). Another drawback is that the PLL lock detection level is susceptible to manufacturing variations.

An example of the prior art that eliminates this smoothing circuit is described in Japanese Laid-open Patent Publication No. H05-022130. When the locked or unlocked state of the PLL is determined using digital circuits, however, there are problems with consistently and reliably determining if the PLL is locked. More specifically, when the unsynchronized signal (the divide-by-n output of the internal VCO) converges on the sync signal (the reference signal, such as the horizontal sync signal of the video signal) when resynchronizing the PLL with the signal phase after the PLL is unlocked from the locked state, the phase overshoots the synchronization point and an erroneous lock detection state is output.

An example of the prior art that can consistently determine the locked state without error when the PLL shifts between locked and unlocked states is taught in U.S. Pat. No. 4,929,916 (corresponding to Japanese Laid-open Patent Publication No. H01-231430). A condition of detecting a locked state in JP-A-H01-231430 is that the locked state continues for a prescribed time (set to the time required by a counter to count to a specific value) before determining the PLL is locked. A problem with this method is that the PLL is determined to be unlocked when there is only a slight phase difference between the phase comparison signal and the reference signal, and an integration circuit is provided to compensate for this problem. Therefore, while external pins are not required a smoothing circuit is required.

FIG. 7 is a block diagram of a conventional PLL lock detection circuit that uses a smoothing circuit. FIG. 8 is a circuit diagram showing the circuit arrangement of selected blocks in FIG. 7. As shown in FIG. 7 this PLL lock detection circuit has a PLL unit 100p, a window generation unit 400, a logic gate unit 500, a charge pump unit 600, a smoothing circuit unit 700, and a Schmidt circuit 800.

The composite sync signal (or horizontal sync signal) SYNp of the video signal is input as the reference signal to the PLL unit 100p, which produces and outputs comparison signal DEVp (the output of 1/N frequency divider 12p which divides the output of the VCO (voltage-controlled oscillator) 11p by N). The window generation unit 400 generates a window signal WN to the timing edge of the comparison signal DEVp. Based on the phase relationship between the horizontal sync signal SYNp and the window signal WN, the logic gate unit 500 outputs a PLL lock charge signal CH if the horizontal sync signal SYNp is in the window signal WN, and outputs the PLL unlock discharge signal DI if the horizontal sync signal SYNp is outside the window signal WN.

The charge pump unit 600 includes a p-channel MOS transistor 61 and an n-channel MOS transistor 62 which are respectively switched on and off by the PLL lock charge signal CH and PLL unlock discharge signal DI, and output PLL detection charge/discharge signal CD.

The smoothing circuit unit 700 levels the PLL detection charge/discharge signal CD and outputs dc voltage LV.

The Schmidt circuit 800 shapes the dc voltage LV and outputs PLL lock detection signal DLKp.

When the horizontal sync signal SYNp is in the window signal WN, the PLL is locked. When the horizontal sync signal SYNp is not in the window signal WN, the PLL is unlocked. The threshold value of the Schmidt circuit 800 sets the switching level for the PLL locked and PLL unlocked states.

When the composite sync signal SYNp is input as the reference signal for phase comparison by the PLL unit 100p, PLL operating errors due to phase comparison between the serration pulse and equivalence pulse must be prevented. A vertical blanking signal BLKp is therefore input to the PLL unit 100p in the vertical flyback period, that is, the vertical blanking period, to stop operation of the PLL unit 100p. This vertical blanking signal BLKp is also input to the logic gate unit 500 to stop input of the PLL lock charge signal CH and PLL unlock discharge signal DI to the charge pump unit 600 during the vertical blanking period.

FIG. 8 shows the internal arrangement of the PLL unit 100p. The PLL unit 100p has a VCO 11p, a frequency divider 12p, a phase comparator 13p, a charge pump 14p, and a smoothing circuit (loop filter) 15p.

The frequency divider 12p divides the output clock signal from the VCO 11p by N and outputs comparison signal DEVp. The phase comparator 13p compares the comparison signal DEVp with the horizontal sync signal SYNp as the reference signal, and outputs phase advance error signal UPp and phase delay error signal DNp. The phase advance error signal UPp and phase delay error signal DNp are input to the charge pump 14p, which outputs pump current signal CPp. The pump current signal CPp is input to the smoothing circuit 15p, which levels the input and outputs dc voltage signal EVp as a feedback signal to the VCO 11p.

FIG. 8 shows the arrangement of the logic gate unit 500 and the charge pump unit 600 of the conventional PLL lock detection unit 1000p that uses a smoothing circuit unit 700. FIG. 9 is a circuit diagram of the phase comparator 13p in the PLL unit 100p. With the phase comparator 13p shown in FIG. 9 the phase advance error signal UPp and the phase delay error signal DNp go inactive when the vertical blanking signal BLKp is low. The pump current signal CPp thus goes to a high impedance level, and the voltage of the smoothing circuit 15p (loop filter) is held steady. During the vertical blanking period the VCO 11p holds the state before vertical blanking.

FIG. 10 is a waveform diagram describing the operation of the phase comparator 13p. The period of the width of the composite (horizontal) sync signal SYNp is the phase comparison period. When the comparison signal DEVp is low and the composite sync signal SYNp is simultaneously high, the NAND gate 132 outputs the phase advance error signal UPp. When the comparison signal DEVp and the composite sync signal SYNp are simultaneously high, the AND gate 133 outputs the phase delay error signal DNp. The charge pump 14p outputs pump current signal CPp based on the phase advance error signal UPp and phase delay error signal DNp, and the dc voltage signal EVp is output from the smoothing circuit 15p.

The operation of the PLL lock detection circuit according to the related art is described next with reference to the waveform diagram shown in FIG. 11. The composite sync signal SYNp that is input at time t1 is input within the width of the window signal WN (when the window signal WN is high), and the NAND 52 of the logic gate unit 500 therefore outputs the PLL lock charge signal CH (negative polarity). The PLL lock charge signal CH turns the p-channel MOS transistor 61 of the charge pump unit 600 on and charges the smoothing circuit (smoothing capacitance) unit 700.

At time t2 and time t3 the composite sync signal SYNp is also input within the width (high period) of the window signal WN, the smoothing circuit (smoothing capacitance) unit 700 therefore continues to be charged and the dc voltage LV gradually rises. At time t3 the dc voltage LV exceeds the threshold level TH of the Schmidt circuit 800, and the PLL lock detection signal DLPp output from the Schmidt circuit 800 to the PLL lock detection pin 30p goes from low to high. More specifically, that the PLL unit 100p has locked is detected. At time t4 the smoothing circuit unit 700 is charged further.

At time t5 the composite sync signal SYNp is input while the window signal WN goes from high to low. From time t1 to time t4, the PLL lock charge signal CH is output when the high period of the composite sync signal SYNp and the low period of the window signal WN overlap. The PLL unlock discharge signal DI (positive polarity) is also output from the AND 53 of the logic gate unit 500 while the high period of the composite sync signal SYNp and the low period of the window signal WN overlap. This turns the n-channel MOS transistor 62 of the charge pump unit 600 on and discharges the smoothing circuit (smoothing capacitance) unit 700.

At time t6 the high composite sync signal SYNp is input during the low period of the window signal WN, and the smoothing circuit unit 700 is therefore discharged while the PLL unlock discharge signal DI is asserted (for the high period of the composite sync signal SYNp). Because the composite sync signal SYNp is input at time t7 and time t8 during the low period of the window signal WN, the smoothing circuit (smoothing capacitance) unit 700 continues discharging and the dc voltage LV gradually drops. As a result, the dc voltage LV goes below the threshold level TH of the Schmidt circuit 800 at time t8, and the PLL lock detection signal DLPp output from the Schmidt circuit 800 to the PLL lock detection pin 30p goes from high to low. More specifically, the PLL unit 100p unlocks and that the PLL unit 100p is unlocked is detected.

Because the PLL lock detection circuit of the related art described above requires a smoothing circuit, external pins and external components are required when the PLL lock detection circuit is integrated, and the locked state detection level is susceptible to manufacturing variations.

### SUMMARY OF THE INVENTION

The PLL lock detection circuit and semiconductor device of the invention achieve a high precision PLL lock detection signal and enable eliminating a smoothing circuit.

A first aspect of the invention is a PLL lock detection circuit operable to detect the phase state of a PLL circuit that generates a signal synchronized to the phase of a reference signal that has a predetermined period and a variable logic level, the PLL lock detection circuit including: a phase comparison unit that compares the reference signal and a comparison signal, and generates a comparison result signal; a smoothing unit that levels the comparison result signal and generates a smoothed signal; an oscillation unit that generates a comparison signal with a period substantially equal to the predetermined period based on the amplitude of the smoothed signal; and a phase state detection unit that detects a phase state and generates a phase state signal based on a logic level of the reference signal or the comparison signal at a prescribed point in the period of the other of the reference signal and the comparison signal.

A semiconductor device according to another aspect of the invention renders the phase state detection unit of this PLL lock detection circuit in a semiconductor chip.

The PLL lock detection circuit of the present invention can reliably detect if the PLL is locked by simultaneously evaluating whether the PLL is locked or unlocked. Furthermore, because determining whether the PLL is locked or unlocked is based on the continuity of the PLL phase state, whether the PLL is locked or unlocked can be determined reliably without error.

Furthermore, by eliminating a smoothing circuit, the need for associated external pins and external components is also eliminated, and the PLL lock detection circuit can therefore be integrated easily with particularly effective results.

Other objects and attainments together with a fuller understanding of the invention will become apparent and appreciated by referring to the following description and claims taken in conjunction with the accompanying drawings.

### BRIEF DESCRIPTION OF THE DRAWINGS

FIG. 1 is a block diagram describing the arrangement of a PLL lock detection circuit according to a first embodiment of the invention.

FIG. 2A is a circuit diagram describing the arrangement of functional blocks in the PLL lock detection circuit according to a first embodiment of the invention.

FIG. 2B is a circuit diagram describing the arrangement of the phase comparator of the PLL lock detection circuit according to a first embodiment of the invention.

FIG. 2C is a waveform diagram describing the operation of the phase comparator of the PLL lock detection circuit according to a first embodiment of the invention.

FIG. 2D is a circuit diagram describing the arrangement of the phase comparator of the PLL lock detection circuit according to a third embodiment of the invention.

FIG. 3 is a circuit diagram describing the arrangement of the PLL lock continuity detection unit in the first embodiment of the invention.

FIG. 4 is a waveform diagram describing the operation of the PLL lock continuity detection unit in the first embodiment of the invention.

FIG. 5 is a waveform diagram describing the operation of the PLL lock detection circuit in the first embodiment of the invention.

FIG. 6A is a circuit diagram describing the arrangement of the PLL lock continuity detection unit in a second embodiment of the invention.

FIG. 6B is a circuit diagram describing the arrangement of the PLL lock continuity detection unit in a second embodiment of the invention.

FIG. 7 is a block diagram describing the arrangement of a PLL lock detection circuit according to the prior art.

FIG. 8 is a circuit diagram describing the arrangement of functional blocks in the PLL lock detection circuit according to the prior art.

FIG. 9 is a circuit diagram describing the arrangement of the phase comparator of the PLL lock detection circuit according to the prior art.

FIG. 10 is a waveform diagram describing the operation of the phase comparator of the PLL lock detection circuit according to the prior art.

FIG. 11 is a waveform diagram describing the operation of the PLL lock detection circuit according to the prior art.

### DETAILED DESCRIPTION OF THE PREFERRED EMBODIMENTS

Preferred embodiments of the present invention are described below with reference to the accompanying figures. Note that parts functionally having the same arrangement, operation, and effect are identified by the same reference numerals in the accompanying figures. All numeric values used below are used by way of example to describe the invention in detail, and the invention is not limited to the cited values. Logic levels referred to as high and low herein are also used by way of example to describe the invention in detail, and the invention is not limited to the logic levels described below.

### Embodiment 1

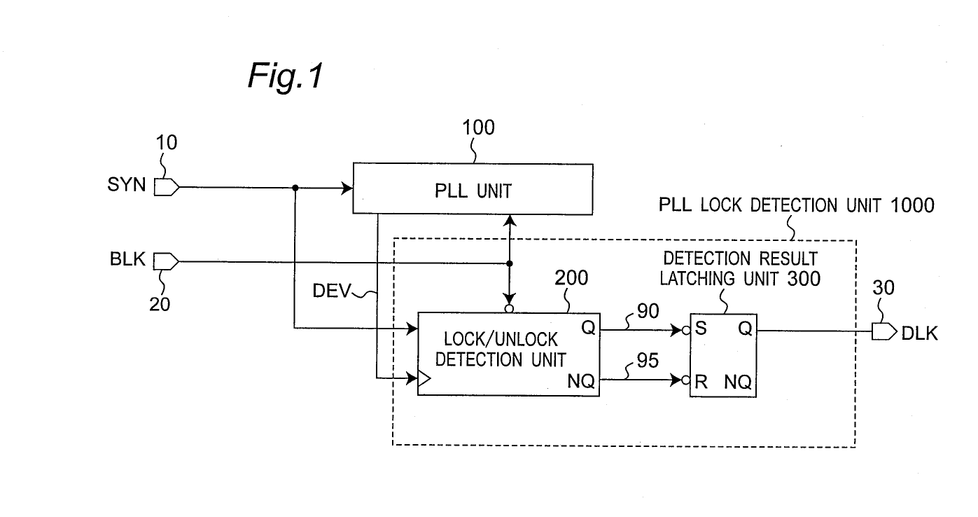

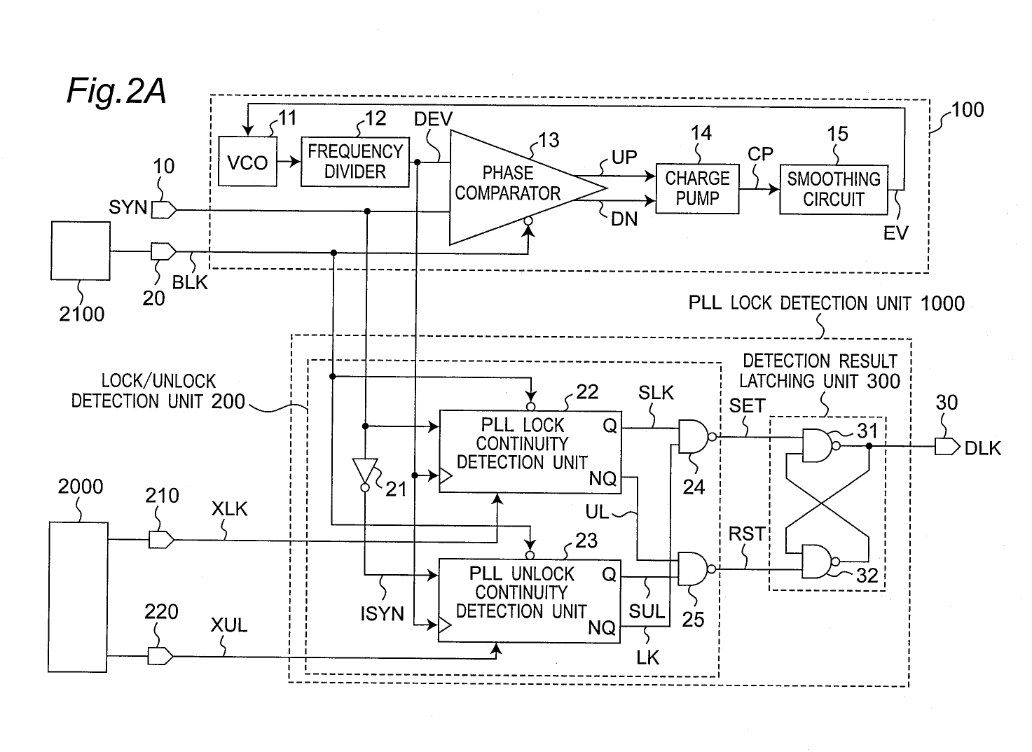

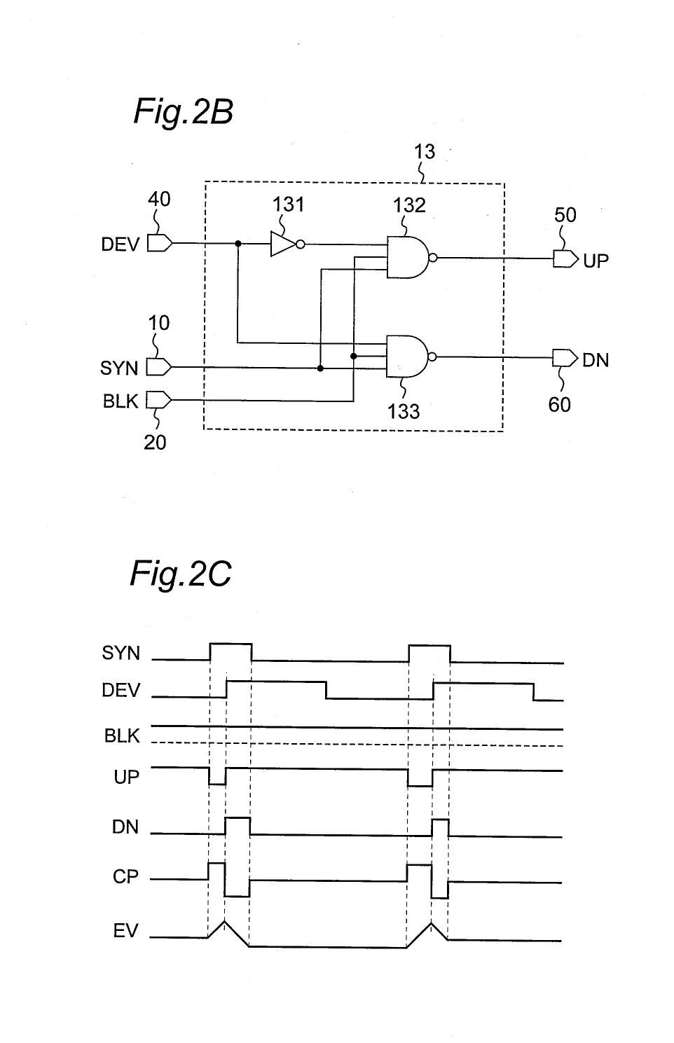

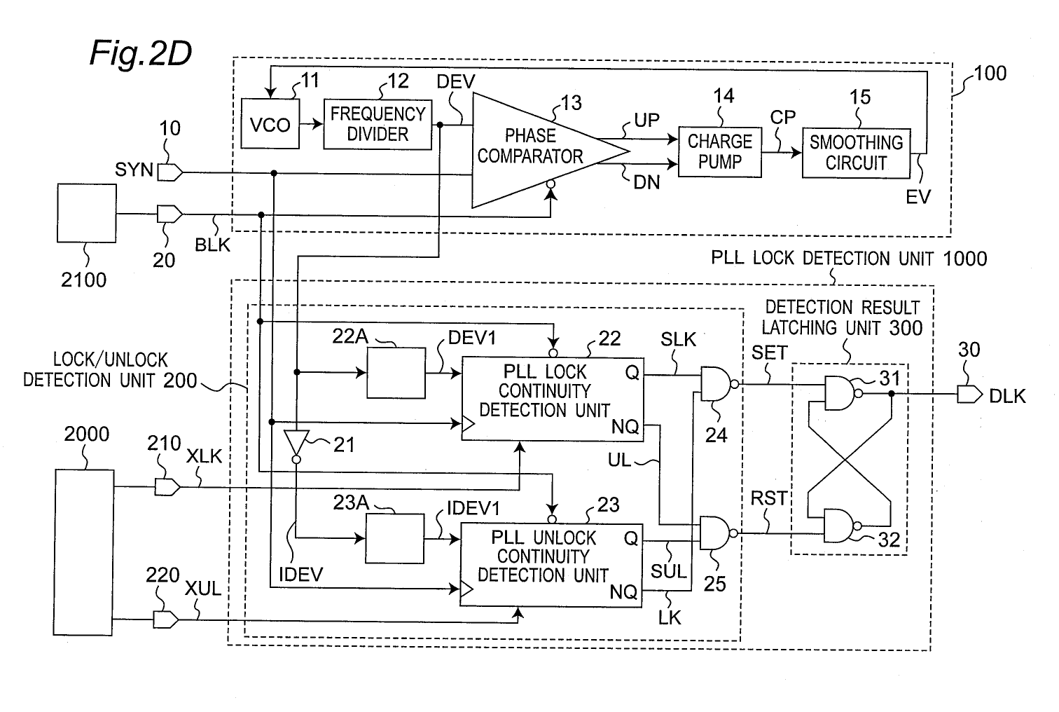

FIG. 1 is a block diagram describing the arrangement of a PLL lock detection circuit according to a first embodiment of the invention. FIG. 2A is a circuit diagram describing the arrangement of functional blocks in the PLL lock detection circuit shown in FIG. 1.

The PLL lock detection circuit according to this first embodiment of the invention includes a PLL unit 100 and a PLL lock detection unit 1000.

The PLL lock detection unit 1000 has a lock/unlock detection unit 200 and a detection result latching unit 300.

The composite sync signal SYN and the vertical blanking signal BLK are input to both the PLL unit 100 and the PLL lock detection unit 1000. The comparison signal DEV that is input to the phase comparator 13 in the PLL unit 100 is also input for sampling the composite sync signal SYN to the PLL lock detection unit 1000.

The PLL lock detection circuit according to this first embodiment of the invention detects the phase state of the PLL unit 100. Because the vertical blanking signal BLK denotes a predetermined period, it is also referred to as a predetermined period signal and is generated by a predetermined period signal generation unit 2100.

A reference signal, such as the composite sync signal (or horizontal sync signal) SYN of the video signal, that has a predetermined period and a variable logic level is input to the PLL unit 100, which outputs a comparison signal DEV (the output of the 1/N frequency divider 12 that frequency divides the output of the VCO (voltage-controlled oscillator) 11) synchronized to the phase of the reference signal. The comparison signal DEV has a period that is substantially equal to the predetermined period of the reference signal.

When the composite sync signal SYN is input as the reference signal for phase comparison by the PLL unit 100, PLL operating errors due to phase comparison between the serration pulse and equivalence pulse must be prevented. A vertical blanking signal BLK is therefore input to the PLL unit 100 in the vertical flyback period, that is, the vertical blanking period, to stop operation of the PLL unit 100 in the vertical blanking period.

FIG. 2A shows the internal arrangement of the PLL unit 100. The PLL unit 100 has a VCO 11, a frequency divider 12, a phase comparator 13, a charge pump 14, and a smoothing circuit (loop filter) 15.

The VCO 11 and the frequency divider 12 render an oscillation unit. The phase comparator 13 and the charge pump 14 render a phase comparison unit. The smoothing circuit 15 is also referred to as a smoothing unit.

The frequency divider 12 divides the output clock signal of the VCO 11 by N to output the comparison signal DEV. The phase comparator 13 compares the comparison signal DEV with the composite sync signal SYN as the reference signal, and outputs the phase advance error signal UP and phase delay error signal DN. The phase advance error signal UP and phase delay error signal DN are input to the charge pump 14, which outputs pump current signal CP. The pump current signal CP is input to the smoothing circuit 15, which levels the input and outputs dc voltage signal EV as a feedback signal to the VCO 11.

The pump current signal CP is also referred to as a comparison result signal, and the dc voltage signal EV is also referred to as a smoothed signal.

FIG. 2B is a circuit diagram of the phase comparator 13 in the PLL unit 100. With the phase comparator 13 shown in FIG. 2B the phase advance error signal UP and the phase delay error signal DN go inactive when the vertical blanking signal BLK is low. The pump current signal CP thus goes to a high impedance level, the voltage of the smoothing circuit 15 (loop filter) is held steady, and the VCO 11 holds the state before vertical blanking during the vertical blanking period.

FIG. 2C is a waveform diagram describing the operation of the phase comparator 13. The period of the width of the composite (horizontal) sync signal SYN is the phase comparison period. When the comparison signal DEV is low and the composite sync signal SYN is also high, the NAND gate 132 outputs the phase advance error signal UP. The AND gate 133 outputs the phase delay error signal DN when the comparison signal DEV and the composite sync signal SYN are simultaneously high. The charge pump 14 outputs pump current signal CP based on the phase advance error signal UP and phase delay error signal DN, and the dc voltage signal EV is output from the smoothing circuit 15.

If the rising edge of the comparison signal DEV is in the period when the composite sync signal SYN is also high, the dc voltage signal EV rises or falls so that the output clock signal of the VCO 11 remains substantially constant. In this state the PLL unit 100 is locked (PLL locked state). This locked state is also referred to as a pseudo-locked state (PLL pseudo-locked state). If the rising edge of the comparison signal DEV is not in the period when the composite sync signal SYN is high, the PLL unit 100 is unlocked (PLL unlocked state). This unlocked state is also referred to as a pseudo-unlocked state (PLL pseudo-unlocked state).

The internal circuit arrangements of the lock/unlock detection unit 200 and the detection result latching unit 300 in the PLL lock detection unit 1000 are described next.

The lock/unlock detection unit 200 includes a PLL lock continuity detection unit 22, a PLL unlock continuity detection unit 23, an inverter 21, a NAND gate 24, and a NAND gate 25.

The normal composite sync signal SYN is input to the inverter 21, which outputs the inverted sync signal ISYN. The PLL lock continuity detection unit 22 and the PLL unlock continuity detection unit 23 are reset by the vertical blanking signal BLK, and sample the normal composite sync signal SYN and the inverted sync signal ISYN, respectively, using the comparison signal DEV, which is the input signal to the phase comparator 13 of the PLL unit 100, as a common sampling clock.

The NAND gate 24 outputs the NOT-AND of the PLL sustained lock signal SLK and the PLL lock signal LK as the PLL lock detection set signal SET. The PLL sustained lock signal SLK denotes the non-inverted output of the PLL lock continuity detection unit 22, and the PLL lock signal LK denotes the inverted output of the PLL unlock continuity detection unit 23.

The NAND gate 25 outputs the NOT-AND of the PLL unlock signal UL and the PLL sustained unlock signal SUL as the PLL lock detection reset signal RST. The PLL unlock signal UL denotes the inverted output of the PLL lock continuity detection unit 22, and the PLL sustained unlock signal SUL denotes the non-inverted output of the PLL unlock continuity detection unit 23.

The detection result latching unit 300 has an R-S latch composed of NAND gates 31 and 32. The output of each of the NAND gates 31 and 32 is connected to an input of the other NAND gate. The PLL lock detection set signal SET and the PLL lock detection reset signal RST are input to the other input node of NAND gate 31 and NAND gate 32, respectively. The output node of one of the NAND gates 31 and 32 rendering the R-S latch is connected to the PLL lock detection signal output node 30.

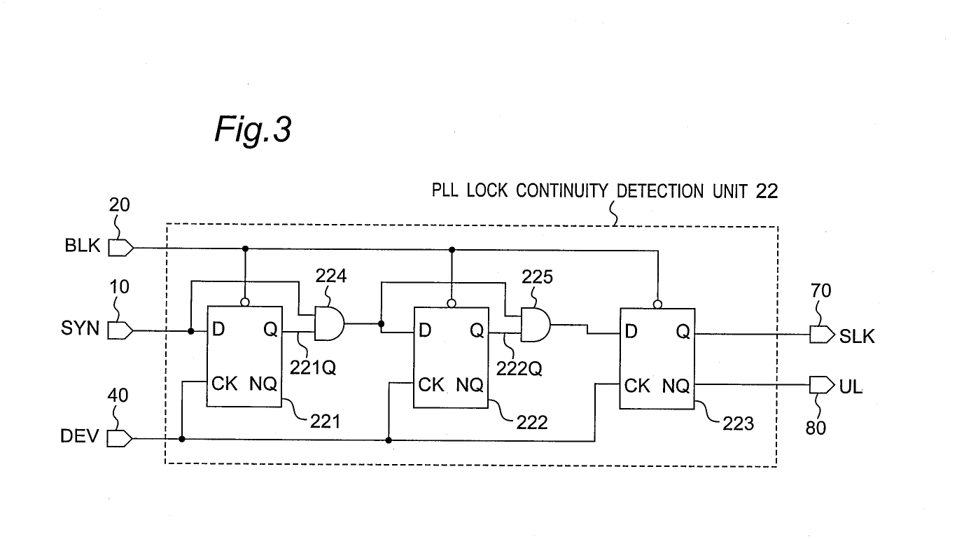

FIG. 3 is a circuit diagram showing the internal arrangement of the PLL lock continuity detection unit 22. When H is one period of the horizontal sync signal, the PLL is determined to be locked when the PLL pseudo-locked state continues for a period of 3H. The PLL lock continuity detection unit 22 includes flip-flops 221, 222, 223 and AND gates 224 and 225.

The flip-flops 221, 222, 223 are reset at the vertical blanking signal BLK, and the comparison signal DEV is input to the clock input node.

The output of AND gate 225 is connected to the D input node of flip-flop 223, one input is connected to the non-inverted output node of flip-flop 222, and the other input is connected to the D input node of flip-flop 222.

The output of AND gate 224 is connected to the D input node of flip-flop 222 and the other input of AND gate 225, one input is connected to the non-inverted output node of flip-flop 221, and the other input is connected to the D input node of flip-flop 221 and the composite sync signal input node 10.

The PLL lock continuity detection unit 22 outputs the PLL sustained lock signal SLK from the non-inverted output node of flip-flop 223, and outputs the PLL sustained unlock signal SUL from the inverted output node of the flip-flop 223.

The arrangement of the PLL unlock continuity detection unit 23 is basically identical to the arrangement of the PLL lock continuity detection unit 22 shown in FIG. 3. While the PLL lock continuity detection unit 22 uses the normal composite sync signal SYN that is input to the composite sync signal input node 10, however, the PLL unlock continuity detection unit 23 uses the inverted sync signal ISYN of the composite sync signal SYN input from the inverter 21.

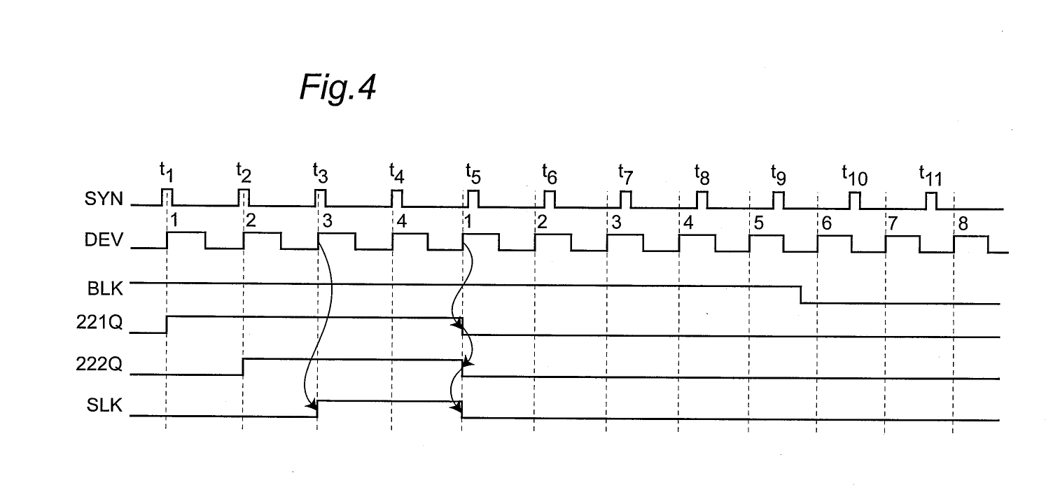

FIG. 4 is a waveform diagram describing the operation of the PLL lock continuity detection unit 22.

The comparison signal DEV is the output signal of the divide-by-N frequency divider 12 in the PLL unit 100, is the comparison signal input to the phase comparator 13, and is the clock signal of the flip-flops 221, 222, 223 in the PLL lock continuity detection unit 22 and the PLL unlock continuity detection unit 23. The continuity (number of periods H) of the pseudo-locked state that is the threshold value for PLL lock detection can be programmatically set in registers for the PLL lock continuity detection unit 22 and the PLL unlock continuity detection unit 23 of the lock/unlock detection unit 200 in the PLL lock detection unit 1000.

At time t1 the rising edge of the comparison signal DEV is in the high period of the composite sync signal SYN, and the PLL unit 100 is locked (pseudo-locked state) as described in FIG. 2C. Because the composite sync signal SYN is high at the rising edge of the comparison signal DEV, the non-inverted output 221Q of flip-flop 221 goes from low to high. From time t2 to time t4 the rising edge of the comparison signal DEV is still within the width (high period) of the composite sync signal SYN, and the PLL unit 100 is therefore locked.

Because the composite sync signal SYN is high and the non-inverted output (output Q) of flip-flop 221 is high, the non-inverted output 222Q of flip-flop 222 goes from low to high. Likewise at time t3, the PLL sustained lock signal SLK denoting the non-inverted output of the flip-flop 223 goes from low to high, and that the PLL pseudo-locked state continued for the period of 3H can be detected. Because the rising edge of the comparison signal DEV is within the width (high period) of the composite sync signal SYN at time t4, the PLL is locked but there is no change in the internal operation of the PLL lock continuity detection unit 22. When the PLL sustained lock signal SLK is high, the locked state is also called a “true locked state” (true PLL locked state). The PLL lock continuity detection unit 22 outputs the PLL sustained lock signal SLK in this true PLL locked state.

At time t5 the rising edge of the comparison signal DEV is not within the width (high period) of the composite sync signal SYN. The rising edge of the comparison signal DEV is input when the D input to flip-flop 221, flip-flop 222, and flip-flop 223 is low. The non-inverted output of flip-flop 221, flip-flop 222, and flip-flop 223 therefore returns from high to low, and the PLL sustained lock signal SLK also goes from high to low. The PLL unit 100 thus goes to a pseudo-unlocked state. The vertical blanking signal BLK input between time t9 and time t10 resets the flip-flops 221, 222, 223.

The inverted composite sync signal SYN is input through the inverter 21 shown in FIG. 2A to the PLL unlock continuity detection unit 23. When the PLL sustained lock signal SLK goes low, the PLL goes to the pseudo-unlocked state, and if this pseudo-unlocked state continues for a 3H period, the PLL sustained unlock signal SUL goes from low to high. That the pseudo-unlocked state has continued for 3H can thus be detected.

When the PLL sustained unlock signal SUL is high the unlocked state is called a “true unlocked state” (true PLL unlocked state). The PLL unlock continuity detection unit 23 generates the PLL sustained unlock signal SUL in this true PLL unlocked state.

When the PLL unit 100 is in the true locked state, the PLL sustained lock signal SLK and the PLL lock signal LK are both high, and the PLL lock detection set signal SET in FIG. 2A is low. When the PLL unit 100 is in the true unlocked state, the PLL sustained unlock signal SUL and the PLL unlock signal UL are both high, and the PLL lock detection reset signal RST therefore goes low.

The PLL lock detection set signal SET is therefore output continuously when the PLL unit 100 is in the true locked state, and the PLL lock detection reset signal RST is not output.

When the PLL unit 100 is in the true unlocked state, the PLL lock detection reset signal RST is output continuously and the PLL lock detection set signal SET is not output.

The lock/unlock detection unit 200 described above thus outputs the PLL lock detection set signal SET and the PLL lock detection reset signal RST. The PLL lock detection set signal SET and the PLL lock detection reset signal RST are input to two input nodes of the detection result latching unit 300, which outputs the PLL lock detection signal DLK.

The PLL lock detection unit 1000 is also called a phase state detection unit, and the PLL lock detection signal DLK is also called a phase state signal. The PLL lock detection unit 1000 thus detects the phase state of the PLL unit 100 and generates the phase state detection signal DLK.

Therefore, when the PLL unit 100 is in the true locked state and a low composite sync signal SYN is sampled even once at the rising edge of the comparison signal DEV, the PLL sustained lock signal SLK goes low and the PLL lock detection set signal SET goes high. The PLL lock detection signal DLK remains high, however. If the composite sync signal SYN is low at three consecutive rising edges of the comparison signal DEV, the PLL lock detection signal DLK goes from high to low, denoting the true unlocked state.

Likewise, if the PLL unit 100 is in the true unlocked state and a high composite sync signal SYN is sampled even once at the rising edge of the comparison signal DEV, the PLL sustained unlock signal SUL goes low and the PLL lock detection reset signal RST goes high. The PLL lock detection signal DLK remains low. If the composite sync signal SYN is high at three consecutive rising edges of the comparison signal DEV, the PLL lock detection signal DLK goes from low to high, denoting the true locked state.

From the start of the true locked state to the start of the true unlocked state is also called the lock detection state, and from the start of the true unlocked state to the start of the true locked state is also called the unlock detection state. When the PLL lock detection signal DLK is high denotes the lock detection state, and when the PLL lock detection signal DLK is low denotes the unlock detection state.

As a result, the detection result latching unit 300, or the PLL lock detection unit 1000, can determine the lock detection state when the PLL unit 100 is continuously locked and the unlock detection state when the PLL unit 100 is continuously unlocked. In other words, the PLL lock detection unit 1000 outputs the PLL lock detection signal DLK when the phase state in which the logic level of the composite sync signal SYN is the same at the rising edge of the comparison signal DEV continues for three consecutive periods of the composite sync signal SYN.

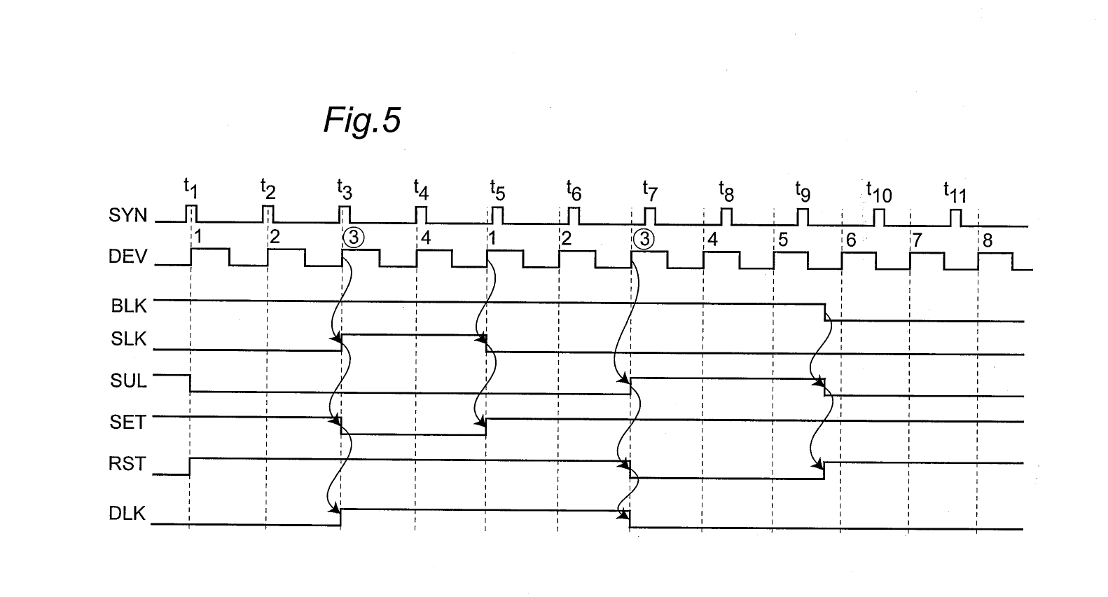

The main operating signals of the PLL lock detection unit 1000 are shown in FIG. 5 and described below.

From time t1 to time t4 in FIG. 5 the rising edge of the comparison signal DEV is within the width (high period) of the composite sync signal SYN, and the PLL unit 100 is locked. The PLL sustained lock signal SLK goes from low to high at time t3 after a period of 3H. The PLL lock detection unit 1000 is thus in the true locked state. When the PLL lock detection set signal SET goes low, the detection result latching unit 300 is set and the PLL lock detection signal DLK goes from low to high. The PLL lock detection unit 1000 thus determines the PLL unit 100 is locked.

At time t5 the rising edge of the comparison signal DEV is not within the width (high period) of the composite sync signal SYN, that is, the rising edge is asserted when the composite sync signal SYN is low, and the PLL unit 100 is in the pseudo-unlocked state. The PLL sustained lock signal SLK returns from high to low. The PLL lock detection set signal SET also returns to high, but the detection result latching unit 300 holds the PLL lock detection signal DLK high at this time.

If this state continues for another 2H, the rising edge of the comparison signal DEV from time t5 to time t7 is input three times consecutively (3H) while the composite sync signal SYN is low. The PLL sustained unlock signal SUL therefore goes from low to high near time t7, and the PLL unit 100 is determined to be in the true unlocked state. Because the PLL lock detection reset signal RST goes low, the detection result latching unit 300 is reset and the PLL lock detection signal DLK goes from high to low. The PLL lock detection unit 1000 thus determines the PLL unit 100 is unlocked.

When the vertical blanking signal BLK is input near time t9, the detection result latching unit 300 holds the logic level of the PLL lock detection signal DLK and stops detecting whether the PLL unit 100 is locked or unlocked during the vertical blanking period of the video signal. Because the duty factor of the equivalence pulse, the serrated pulse, and the vertical sync signal pulse varies during the vertical blanking period, PLL lock/unlock detection errors can occur in the PLL lock detection unit 1000. However, these errors can be prevented if detection stops during the vertical blanking period. This state of the PLL unit 100 in the vertical blanking period is called the PLL hold state.

In the PLL lock detection circuit according to this first embodiment of the invention the PLL lock detection unit 1000 can be rendered as a semiconductor integrated chip. This semiconductor chip can also contain the PLL unit 100.

The PLL lock detection circuit according to this first embodiment of the invention can reliably determine if the PLL is locked by simultaneously evaluating the locked and unlocked states.

Furthermore, because both locked and unlocked states are based on the continuity of the PLL phase state, the PLL state can be reliably detected without error. External pins and external components are also not needed because a smoothing circuit is not needed, thus making integration easier with extremely effective results.

The PLL unit 100 is described synchronizing to a composite sync signal or horizontal sync signal, but the invention is not so limited and the PLL unit 100 can synchronize to any signal with a regular period.

### Embodiment 2

A second embodiment of the invention is described based on the differences with the first embodiment. Other aspects of the arrangement, operation, and effect of the second embodiment are the same as those of the first embodiment, and further description thereof is omitted.

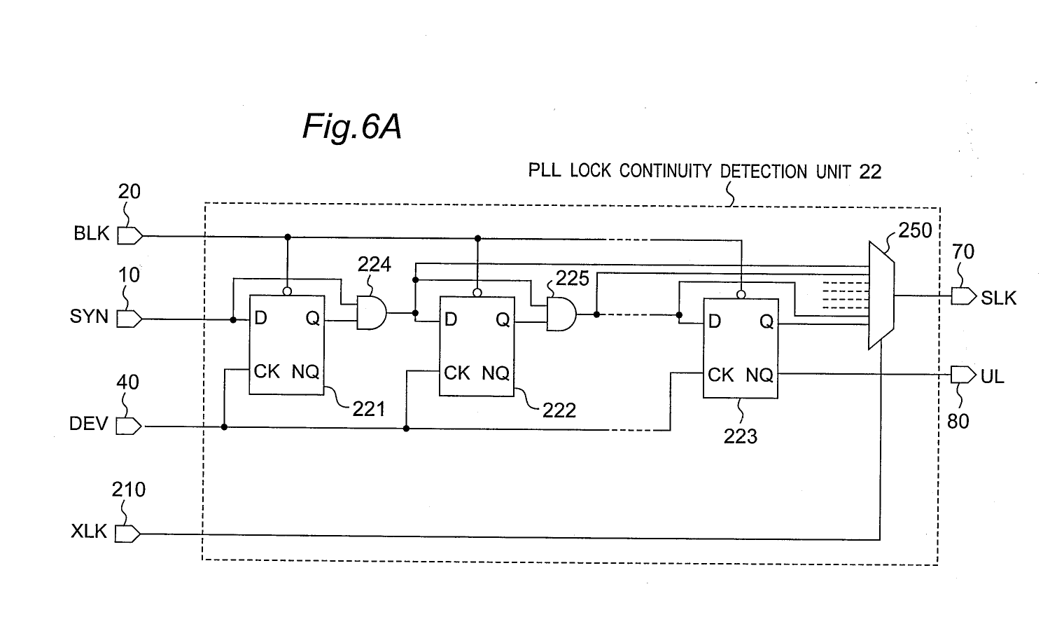

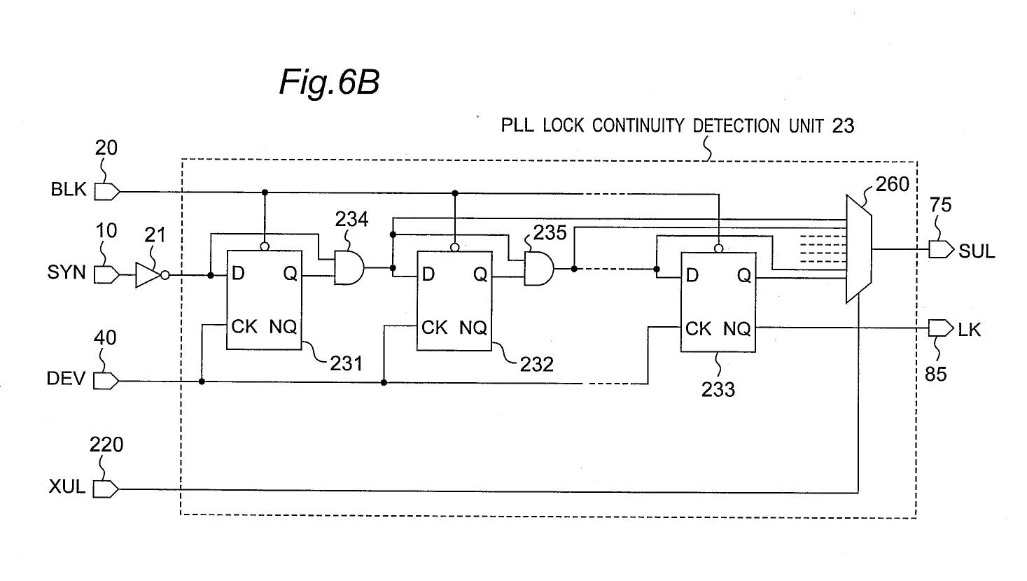

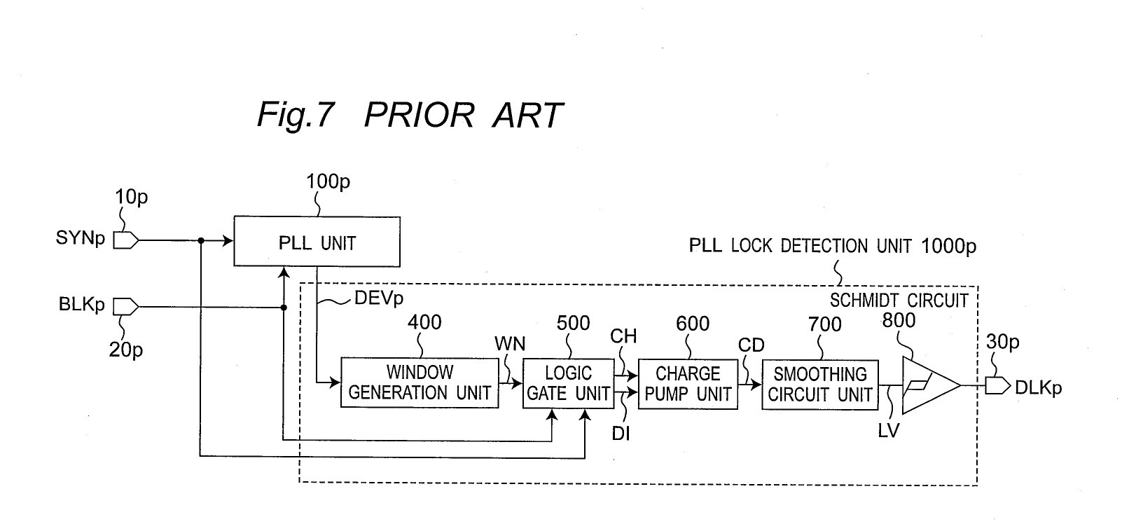

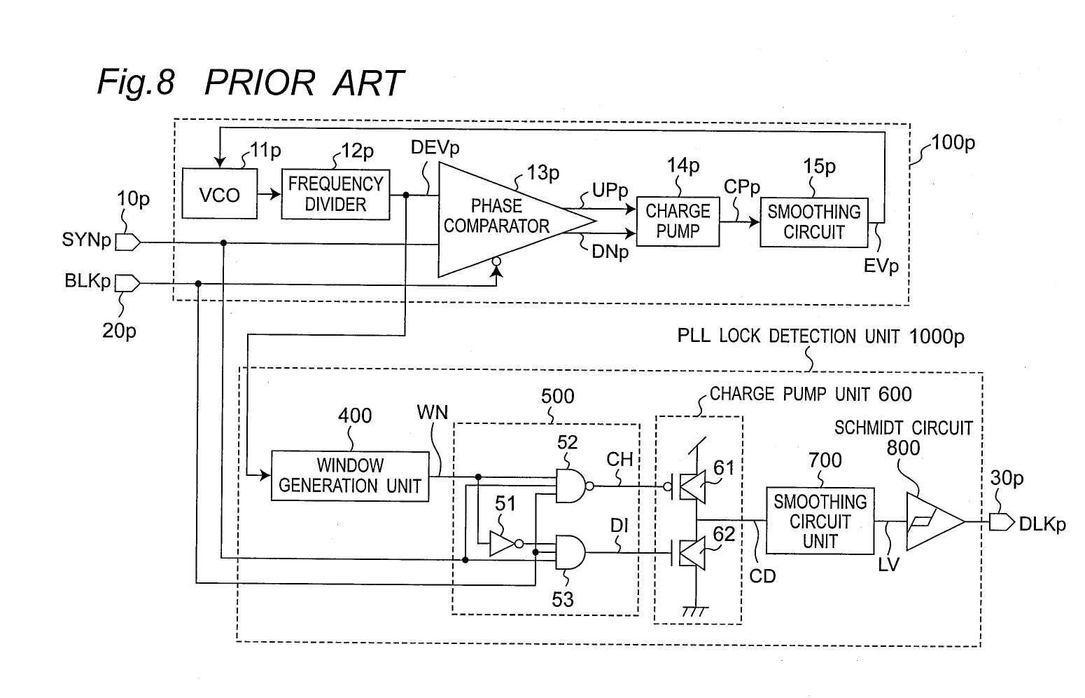

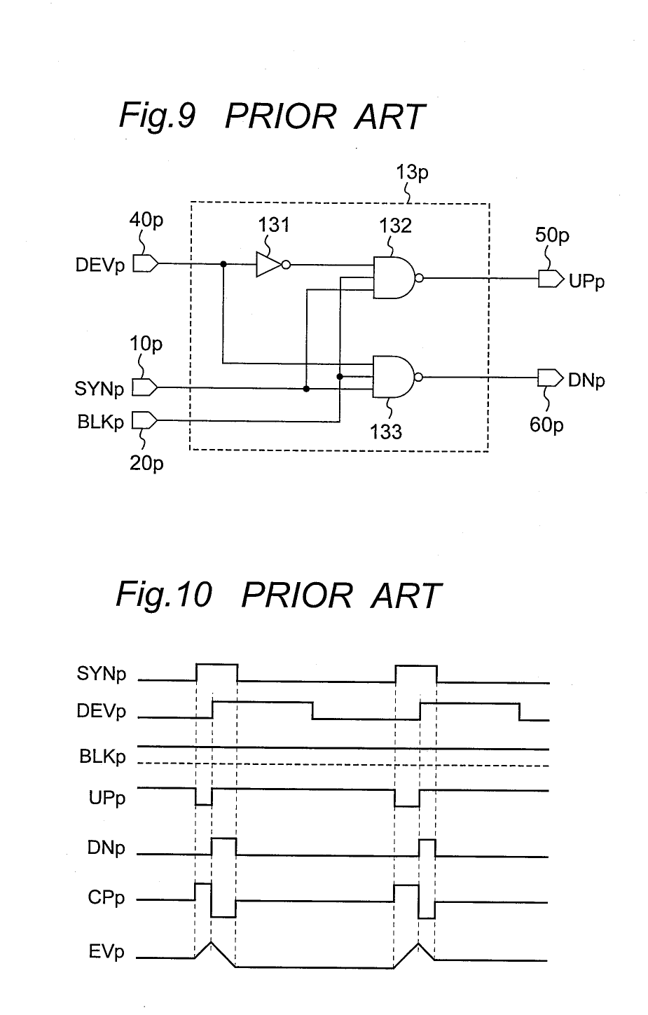

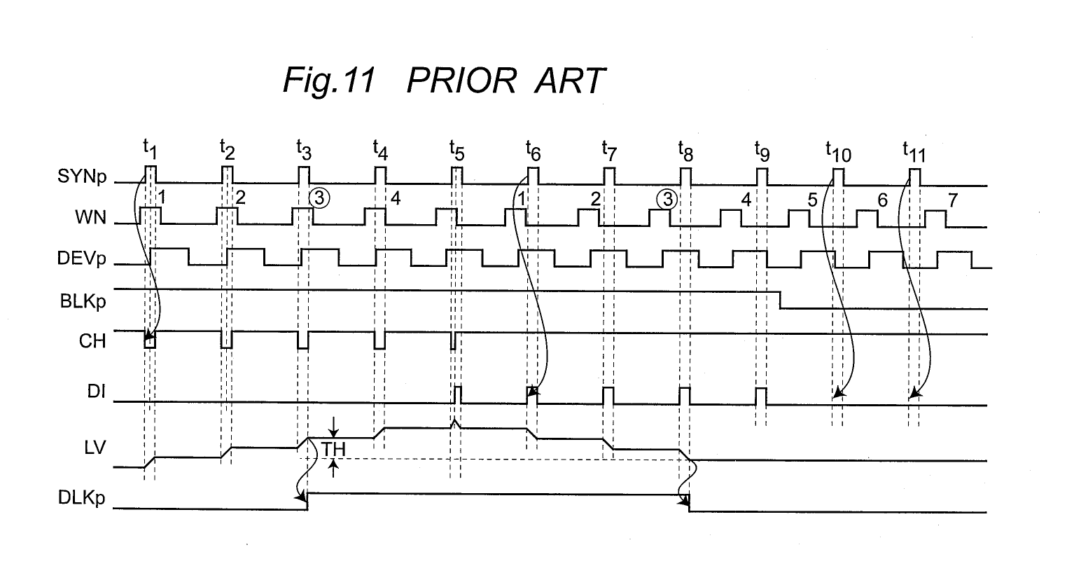

FIG. 6A and FIG. 6B are circuit diagrams of the continuity detection unit 22 and continuity detection unit 23 in the second embodiment of the invention. In FIG. 2A the continuity count setting unit 2000 sets a number of consecutive N (where N is an integer of 2 or more), and generates lock continuity count signal XLK and unlock continuity count signal XUK. The lock continuity count signal XLK and unlock continuity count signal XUK are input to input node 210 and input node 220, respectively, in FIG. 6A and FIG. 6B.

Based on the lock continuity count signal XLK, a selection unit 250 selects either the signal input to the D input node of the flip-flops of the continuity detection unit 22, except for the first flip-flop 221, or the signal output from the Q output node of flip-flop 223, and outputs the PLL sustained lock signal SLK.

Similarly, based on the unlock continuity count signal XUK, a selection unit 260 selects either the signal input to the D input node of the flip-flops of the continuity detection unit 23, except for flip-flop 223, or the signal output from the Q output node of flip-flop 233, and outputs the PLL sustained unlock signal SUL.

The PLL lock detection unit 1000 having the continuity detection units 22 and 23 according to this second embodiment of the invention outputs the PLL lock detection signal DLK when the phase state in which the logic level of the composite sync signal SYN at the rising edge of the comparison signal DEV remains the same for N consecutive periods of the composite sync signal SYN. This arrangement enables setting the number N of consecutive horizontal synchronization periods that is used as the standard for determining if the PLL is in the true locked state or true unlocked state, and thus affords a PLL lock detection circuit enabling greater freedom than the first embodiment.

### Embodiment 3

A third embodiment of the invention is described based on the differences with the first and second embodiments. Other aspects of the arrangement, operation, and effect of the third embodiment are the same as those of the first and second embodiments, and further description thereof is omitted.

FIG. 2D is a circuit diagram showing the arrangement of the phase comparator in the PLL lock detection circuit according to a third embodiment of the invention. The PLL lock continuity detection unit 22 and the PLL unlock continuity detection unit 23 in the first embodiment shown in FIG. 2A respectively sample the uninverted composite sync signal SYN and the inverted sync signal ISYN using the comparison signal DEV as a common sampling clock.

The PLL lock continuity detection unit 22 and the PLL unlock continuity detection unit 23 of the third embodiment shown in FIG. 2D sample the uninverted comparison signal DEV and the inverted comparison signal IDEV using the composite sync signal SYN as the common sampling clock.

Duty factor changing unit 22A and duty factor changing unit 23A change the duty factor of the normal comparison signal DEV and the inverted comparison signal IDEV, and respectively generate changed comparison signal DEV1 and changed comparison signal IDEV1. Using the composite sync signal SYN as a common sampling clock, the PLL lock continuity detection unit 22 and the PLL unlock continuity detection unit 23 sample the changed comparison signal DEV1 and changed comparison signal IDEV1, respectively. By thus adjusting the sampling period of both the normal comparison signal DEV and the inverted comparison signal IDEV, the phase state of the PLL unit 100 can be detected with greater precision.

The sampling clock in the first embodiment is the comparison signal DEV, and in this third embodiment is the composite sync signal (reference signal) SYN. The sampled signals are the composite sync signal (reference signal) SYN in the first embodiment and the comparison signal DEV in this third embodiment. The sampling point of the sampling clocks is at the rising edge of the clock signal in both the first embodiment and the third embodiment, but the falling edge can be used instead. More generally, the logic level of one signal can be sampled at a prescribed time (point) in the period of another signal. The rising edge and the falling edge are also referred to as simply the edge.

As described above a PLL lock detection circuit and semiconductor device according to the present invention include a PLL lock detection unit (phase state detection unit) 1000, and can reliably detect if the PLL is locked by simultaneously evaluating whether the PLL is locked or unlocked. Furthermore, because determining whether the PLL is locked or unlocked is based on the continuity of the PLL phase state, whether the PLL is locked or unlocked can be determined reliably without error.

Yet further, because a smoothing circuit is not required by the PLL lock detection unit 1000, the need for associated external pins and external components is eliminated by eliminating the smoothing circuit. The PLL lock detection circuit can therefore be integrated easily with particularly effective results.

The present invention can be used in a PLL lock detection circuit and a semiconductor device.

Although the present invention has been described in connection with the preferred embodiments thereof with reference to the accompanying drawings, it is to be noted that various changes and modifications will be apparent to those skilled in the art. Such changes and modifications are to be understood as included within the scope of the present invention as defined by the appended claims, unless they depart therefrom.

What is claimed is:

1. A PLL lock detection circuit operable to detect the phase state of a PLL circuit that generates a signal synchronized to the phase of a reference signal that has a pulse of a predetermined period and a variable logic level, comprising:
a phase comparison unit that compares the reference signal and a comparison signal, and generates a comparison result signal;
a smoothing unit that levels the comparison result signal and generates a smoothed signal;
an oscillation unit that generates a comparison signal with a period substantially equal to the predetermined period based on the amplitude of the smoothed signal; and
a phase state detection unit that detects a phase state and generates a phase state signal based on a logic level of the reference signal or the comparison signal at a specified point in the period of the other of the reference signal and the comparison signal.

2. The PLL lock detection circuit described in claim 1, wherein said phase state detection unit generates the phase state signal when a phase state in which the logic level at the prescribed point in the period is the same level for N consecutive periods (where N is an integer of 2 or more).

3. The PLL lock detection circuit described in claim 2, wherein said phase state detection unit comprises:
a locked state detection unit that determines the phase state is the locked state when the logic level is a first level;
an unlocked state detection unit that determines the phase state is the unlocked state when the logic level is a second level; and
a phase state signal generating unit generates a phase state signal denoting the state between when the locked state is detected and when the unlocked state is detected.

4. The PLL lock detection circuit described in claim 2, further comprising:
a continuity count setting unit that sets the continuous count N and generates a continuity count signal;
wherein said phase state detection unit generates the phase state signal based on the continuity count signal.

5. The PLL lock detection circuit described in claim 2, further comprising:
a predetermined period signal generating unit that generates a predetermined period signal denoting the predetermined period; and
said phase state detection unit holds the logic level of the phase state signal for the predetermined period based on the predetermined period signal.

6. The PLL lock detection circuit described in claim 1, wherein said phase state detection unit generates the phase state signal based on the logic level of the reference signal at an edge of the comparison signal.

7. The PLL lock detection circuit described in claim 1, wherein said phase state detection unit generates the phase state signal based on the logic level of the comparison signal at an edge of the reference signal.

8. The PLL lock detection circuit described in claim 7, wherein:
said phase state detection unit comprises a duty factor changing unit that changes the duty factor of the comparison signal and generates a changed comparison signal, and
generates a phase state signal based on the logic level of the changed comparison signal.

9. A semiconductor device composed of a single semiconductor chip that is used in a PLL lock detection circuit operable to detect the phase state of a PLL circuit that generates a signal synchronized to the phase of a reference signal that has a predetermined period and a variable logic level, the PLL lock detection circuit including a phase comparison unit that compares the reference signal and a comparison signal, and generates a comparison result signal, a smoothing unit that levels the comparison result signal and generates a smoothed signal, an oscillation unit that generates a comparison signal with a period substantially equal to the predetermined period based on the amplitude of the smoothed signal, and a phase state detection unit that detects a phase state and generates a phase state signal based on a logic level of the reference signal or the comparison signal at a prescribed point in the period of the other of the reference signal and the comparison signal, the semiconductor device comprising:
said phase state detection unit.

10. The semiconductor device described in claim 9, further comprising:
said phase comparison unit;
said smoothing unit; and
said oscillation unit.
